(19) United States
(12) Patent Application Publication
(10) Pub. No.: US 2026/0157005 A1
(43) Pub. Date: Jun. 4, 2026

(54) DISPLAY PANEL AND DISPLAY APPARATUS

(71) Applicant: Tianma Advanced Display Technology Institute (Xiamen) Co.,Ltd., Xiamen (CN)

(72) Inventors: Zhenyu JIA, Xiamen (CN); Xiuli WANG, Xiamen (CN); Zhibo YANG, Xiamen (CN); Wenqi ZHOU, Xiamen (CN)

(21) Appl. No.: 19/062,086

(22) Filed: Feb. 25, 2025

(30) Foreign Application Priority Data
Nov. 29, 2024 (CN) 202411737856.7

(51) Int. Cl. H10H 29/852; H01L 25/16; H10H 29/49; H10H 29/80; H10H 29/85

(52) U.S. Cl. CPC H10H 29/852; H10H 29/49; H10H 29/842; H10H 29/8508; H10W 90/00

(57) ABSTRACT

The present disclosure provides a display panel and display apparatus. The display panel includes an array substrate, including a first surface and a second surface arranged opposite to each other along a direction perpendicular to a light-exiting surface of the display panel, and a plurality of side surfaces connecting the first surface and the second surface, where the plurality of side surfaces includes a first side surface and a second side surface; a plurality of first soldering pads and a plurality of second soldering pads; a plurality of connecting wires at least at the first side, where the plurality of connecting wires is configured to connect the plurality of first soldering pads and the plurality of second soldering pads, and no connecting wire is disposed on the second side; and further includes a plurality of encapsulation structures, at least covering the plurality of side surfaces of the array substrate.

### CROSS-REFERENCE TO RELATED APPLICATION

The present disclosure claims the priority of Chinese Patent Application No. 202411737856.7, filed on Nov. 29, 2024, the content of which is incorporated herein by reference in its entirety.

### TECHNICAL FIELD

The present disclosure generally relates to the field of display technology and, more particularly, relates to a display panel and a display apparatus.

### BACKGROUND

With continuous development of display technology, more display products, such as mobile phones, tablets, laptops, smart wearable devices and the like, are widely used, which may become an indispensable tool to bring great convenience.

Currently, how to save display fabrication cost while ensuring display product quality has become one of the technical problems need to be solved urgently.

### SUMMARY

One aspect of the present disclosure provides a display panel. The display panel includes an array substrate, including a first surface and a second surface arranged opposite to each other along a direction perpendicular to a light-exiting surface of the display panel, and a plurality of side surfaces connecting the first surface and the second surface, where the plurality of side surfaces includes a first side surface and a second side surface; a plurality of first soldering pads and a plurality of second soldering pads, where the plurality of first soldering pads is at the first side, and the plurality of second soldering pads is at the second side; a plurality of connecting wires at least at the first side, where the plurality of connecting wires is configured to connect the plurality of first soldering pads and the plurality of second soldering pads; and no connecting wire is disposed on the second side; and a plurality of encapsulation structures, at least covering the plurality of side surfaces of the array substrate, where an encapsulation structure at the first side is different from an encapsulation structure at the second side.

Another aspect of the present disclosure provides a display apparatus including a display panel. The display panel includes an array substrate, including a first surface and a second surface arranged opposite to each other along a direction perpendicular to a light-exiting surface of the display panel, and a plurality of side surfaces connecting the first surface and the second surface, where the plurality of side surfaces includes a first side surface and a second side surface; a plurality of first soldering pads and a plurality of second soldering pads, where the plurality of first soldering pads is at the first side, and the plurality of second soldering pads is at the second side; a plurality of connecting wires at least at the first side, where the plurality of connecting wires is configured to connect the plurality of first soldering pads and the plurality of second soldering pads; and no connecting wire is disposed on the second side; and a plurality of encapsulation structures, at least covering the plurality of side surfaces of the array substrate, where an encapsulation structure at the first side is different from an encapsulation structure at the second side.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

To clearly explain embodiments of the present disclosure or the technical solutions in the existing technology, the drawings needed for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a planar schematic of a display panel according to various embodiments of the present disclosure.

FIG. 2 illustrates a planar schematic of a back of a display panel according to various embodiments of the present disclosure.

FIG. 3 illustrates a cross-sectional view of a display panel along an AA direction in FIG. 1.

FIG. 4 illustrates a cross-sectional view of a display panel along a BB direction in FIG. 1.

FIG. 5 illustrates a cross-sectional view of a display panel along a CC direction in FIG. 1.

FIG. 6 illustrates a top view of an array substrate and an encapsulation structure on a side of the array substrate according to various embodiments of the present disclosure.

FIG. 7 illustrates another cross-sectional view of a display panel along a BB direction in FIG. 1.

FIG. 8 illustrates another cross-sectional view of a display panel along a CC direction in FIG. 1.

FIG. 9 illustrates another cross-sectional view of a display panel along a BB direction in FIG. 1.

FIG. 10 illustrates another cross-sectional view of a display panel along a CC direction in FIG. 1.

FIG. 11 illustrates another cross-sectional view of a display panel along a BB direction in FIG. 1.

FIG. 12 illustrates another cross-sectional view of a display panel along a CC direction in FIG. 1.

FIG. 13 illustrates another top view of an array substrate and an encapsulation structure on a side of the array substrate according to various embodiments of the present disclosure.

FIG. 14 illustrates another cross-sectional view of a display panel along a BB direction in FIG. 1.

FIG. 15 illustrates another cross-sectional view of a display panel along a CC direction in FIG. 1.

FIG. 16 illustrates a schematic of relative position relationship between a first extension portion and a front of a display panel according to various embodiments of the present disclosure.

FIG. 17 illustrates another schematic of relative position relationship between a first extension portion and a front of a display panel according to various embodiments of the present disclosure.

FIG. 18 illustrates a cross-sectional view of a display panel along a DD direction in FIG. 17.

FIG. 19 illustrates a cross-sectional view of a display panel along an EE direction in FIG. 17.

FIG. 20 illustrates a schematic of relative position relationship between an encapsulation protection layer, a first extension portion and a first protection layer according to various embodiments of the present disclosure.

FIG. 21 illustrates another cross-sectional view of a display panel along a BB direction in FIG. 1.

FIG. 22 illustrates another cross-sectional view of a display panel along a CC direction in FIG. 1.

FIG. 23 illustrates another planar schematic of a display panel according to various embodiments of the present disclosure.

FIG. 24 illustrates another top view of an array substrate and an encapsulation structure on a side of the array substrate according to various embodiments of the present disclosure.

FIG. 25 illustrates another planar schematic of a display panel according to various embodiments of the present disclosure.

FIG. 26 illustrates another planar schematic of a display panel according to various embodiments of the present disclosure.

FIG. 27 illustrates another planar schematic of a display panel according to various embodiments of the present disclosure.

FIG. 28 illustrates another planar schematic of a display panel according to various embodiments of the present disclosure.

FIG. 29 illustrates a structural schematic of a display apparatus according to various embodiments of the present disclosure.

FIG. 30 illustrates another structural schematic of a display apparatus according to various embodiments of the present disclosure.

FIG. 31 illustrates another structural schematic of a display apparatus according to various embodiments of the present disclosure.

### DETAILED DESCRIPTION

To clearly understand above-mentioned objectives, features and advantages of the present disclosure, the solutions of the present disclosure are further described hereinafter. It should be noted that embodiments of the present disclosure and the features in embodiments may be combined with each other if there is no conflict.

Specific details are described in following description to facilitate thorough understanding of the present disclosure, but the disclosure may also be implemented otherwise than as described herein. Obviously, embodiments in the description may be only a part of, not all, embodiments of the present disclosure.

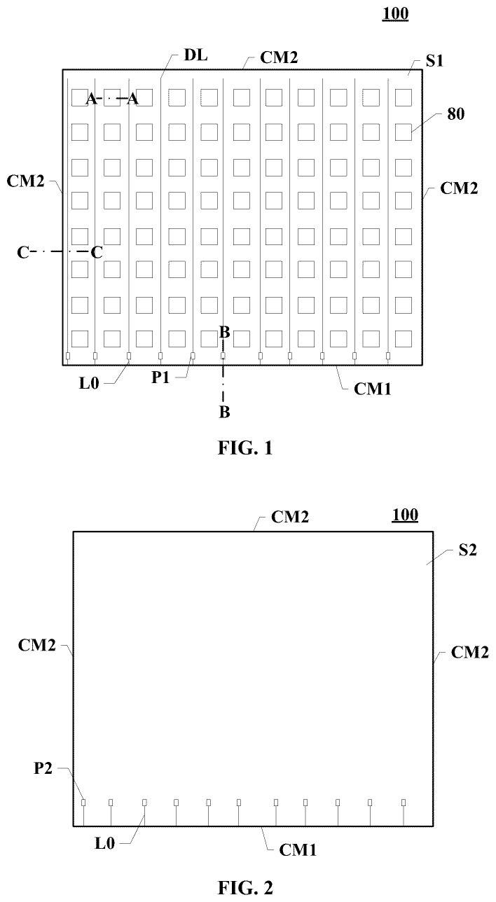

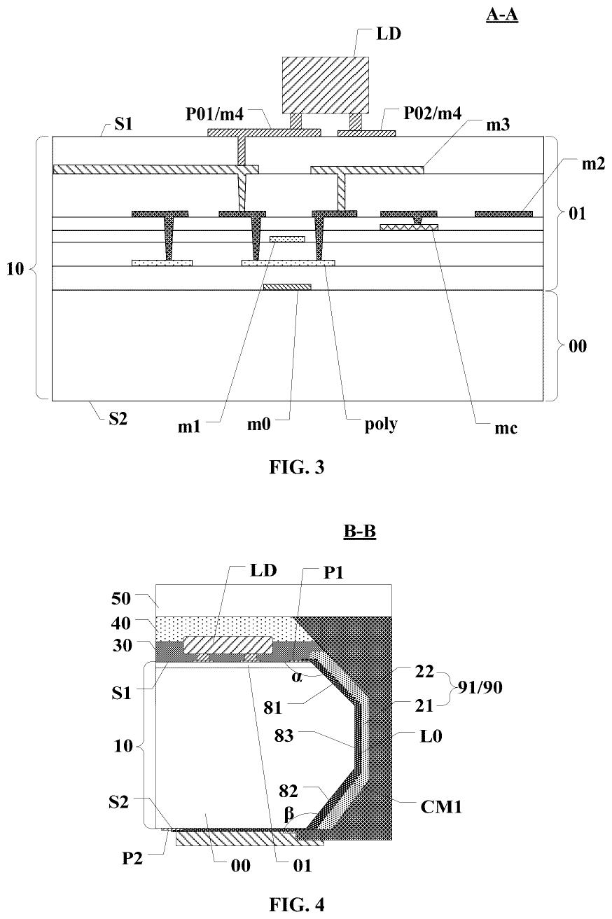

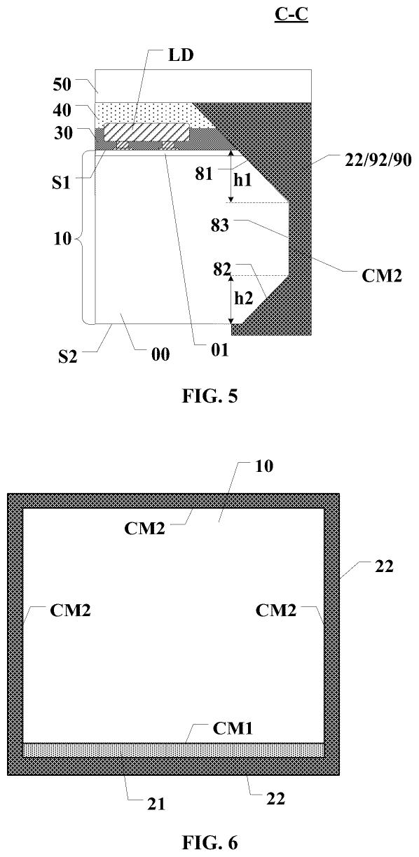

FIG. 1 illustrates a planar schematic of a display panel according to various embodiments of the present disclosure; FIG. 2 illustrates a planar schematic of a back of a display panel according to various embodiments of the present disclosure; FIG. 3 illustrates a cross-sectional view of the display panel along an AA direction in FIG. 1; FIG. 4 illustrates a cross-sectional view of the display panel along a BB direction in FIG. 1; and FIG. 5 illustrates a cross-sectional view of the display panel along a CC direction in FIG. 1. Referring to FIGS. 1, 3, 4 and 5, embodiments of the present disclosure provide a display panel 100. The display panel 100 may include an array substrate 10, where the array substrate 10 may include a first surface S1 and a second surface S2 arranged opposite to each other along the direction perpendicular to the light-exiting surface of the display panel and include side surfaces connecting the first surface S1 and the second surface S2. The side surfaces may include a first side surface CM1 and a second side surface CM2. The first surface S1 may be regarded as a surface disposed with a light-emitting element LD, and the second surface S2 may be a back (non-light-exiting side). FIG. 4 shows the first side surface CM1 of the array substrate 10, and the first side surface CM1 may be disposed with a connecting wire L0. FIG. 5 shows the second side surface CM2 of the array substrate 10, and the second side surface CM2 may be not disposed with a connecting wire. The display panel 100 may further include first soldering pads P1 and second soldering pads P2. The first soldering pad P1 may be on the first surface S1, and the second soldering pad P2 may be on the second surface S2. The first soldering pad P1 may be configured to be connected to a signal line in the first surface S1, for example, connected to a data line DL. The data signal may be transmitted to the data line DL through the first soldering pad P1. The second soldering pad P2 on the second surface S2 may be bound to a control chip or a flexible circuit board, which may be equivalent to setting the binding region of the display panel on the back of the display panel. In such way, the binding region may not need to occupy the space on the front of the display panel, which may be beneficial for realizing extremely narrow frame or frameless design of the display panel and satisfying the splicing requirements of large-size display products. The display panel 100 may further include the connecting wire L0 at least on the first side surface CM1. The connecting wire L0 may be configured to connect the first soldering pad P1 and the second soldering pad P2, such that the signal line on the first surface S1 may be electrically connected to the second soldering pad P2 on the second surface S2, thereby realizing the electrical connection between the signal line on the first surface S1 and the control chip or the flexible circuit board. In the present disclosure, the second side CM2 may be not disposed with the connecting wire L0. The display panel 100 may further include encapsulation structures 90, which may at least cover the side of the array substrate 10 and may be at least configured to encapsulate the side of the array substrate 10 to prevent the influence of water, oxygen and the like on the array substrate 10. The encapsulation structure on the first side CM1 may be different from the encapsulation structure on the second side CM2.

It should be noted that FIG. 1 only takes a display panel with a rectangular structure as an example, which may not limit actual shape of the display panel. In some other embodiments of the present disclosure, the display panel may also be embodied in any other feasible shape such as a circle, a rounded rectangle or the like. Optionally, the display panel provided in one embodiment may be a display panel using inorganic light-emitting diode display technology, such as a Micro LED display panel, a Mini LED display panel or the like. Such type of display panel may have the advantages of high brightness, low power consumption, and easy splicing, and be widely used in display products. The display panel shown in FIG. 1 may only exemplarily illustrate the arrangement manner of the pixel circuits 80 of the light-emitting elements in the display panel, and actual arrangement manner and quantity may be not limited, which may be not limited in the present disclosure. FIG. 1 may not show the light-emitting elements in the display panel, and the light-emitting elements may be evenly arranged on the first surface S1 of the array substrate 10. FIG. 1 may also show the data line DL in the display panel, and the connection between the data line DL and the first soldering pad P1; and the quantity of data lines DL and first soldering pads P1 actually included in the display panel may be not limited. In some embodiments of the present disclosure, the data line DL may be connected to the first soldering pad P1 or may be connected to the first soldering pad P1 through a multiplexing unit to reduce the quantity of first soldering pads P1, which may be not limited in the present disclosure.

It should be noted that FIGS. 4-5 may not illustrate the array layer 01 in the array substrate 10 in detail, where the connection relationship between the array layer 01 and the light-emitting element LD may be referred to FIG. 3. FIG. 3 illustrates the film structure of the array substrate 10 and the connection between the array substrate 10 and the light-emitting element LD, which may not limit actual quantity and size of the film layers of the array substrate. The array substrate 10 may include a substrate 00 and an array layer 01 disposed on the substrate 00. A plurality of transistors may be disposed in the array layer 01. Optionally, the gate electrode of the transistor may be disposed on the first metal layer m1, and the source and drain electrodes of the transistor may be disposed on the second metal layer m2. The array substrate 10 may further include a semiconductor layer poly disposed on the side of the first metal layer m1 facing toward the substrate 00 and include an auxiliary metal layer m0 disposed on the side of the semiconductor layer poly facing toward the substrate 00. It should be noted that the display panel may include a transistor with a single gate structure, where the gate electrode may be located in the first metal layer m1, or the gate electrode may be located in the auxiliary metal layer m0; and the display panel may also include a transistor with a dual gate structure, where one gate electrode of the transistor may be located in the first metal layer m1, and another gate electrode may be located in the auxiliary metal layer m0. Along the direction perpendicular to the plane where the substrate 00 is located, both the first metal layer m1 and the auxiliary metal layer m0 may be overlapped with the semiconductor layer poly, and the auxiliary metal layer m0 may also have a light-blocking function to prevent light from affecting the semiconductor layer poly. Optionally, a capacitor metal layer mc may be further included between the first metal layer m1 and the second metal layer m2; and the capacitor metal layer mc may form a capacitor structure with the second metal layer m2. Optionally, the third metal layer m3 and the fourth metal layer m4 may be also configured on the side of the second metal layer m2 away from the substrate 00; and both the third metal layer m3 and the fourth metal layer m4 may be configured to lay signal lines. In one embodiment, the connection electrodes P01 and P02 of the light-emitting element LD on the array substrate 10 may be on the fourth metal layer m4, and the first soldering pad P1 may be also on the fourth metal layer m4. Optionally, an inorganic film layer may be disposed on the side of the fourth metal layer m4 away from the substrate 00 as needed to protect the connection electrode, which may be not limited in the present disclosure.

FIG. 4 corresponds to the film layer and the encapsulation structure at the first side CM1 of the array substrate 10, and FIG. 5 corresponds to the film layer and the encapsulation structure at the second side CM2 of the array substrate 10. The main difference between FIG. 4 and FIG. 5 is that the first side CM1 may be disposed with the connecting wire L0, the second side CM2 may be not disposed with the connecting wire, and the encapsulation structure corresponding to the first side CM1 may be different from the encapsulation structure corresponding to the second side CM2. In one embodiment, the encapsulation structure of the first side surface CM1 may refer to the encapsulation structure disposed on the first side surface CM1 along the direction which is in parallel with the first surface S1 and the second surface S2, perpendicular to the side surface of the substrate 00 and points from the substrate 00 to the outside. The encapsulation structure of the second side surface CM2 may refer to the encapsulation structure disposed on the second side surface CM2 along the direction which is in parallel with the first surface S1 and the second surface S2, perpendicular to the side surface of the substrate 00 and points from the substrate 00 to the outside. In embodiments of the present disclosure, the connecting wire L0 may be disposed on the first side CM1, while the connecting wire L0 may be not disposed on the second side CM2. For whether the connecting wire L0 is disposed, the encapsulation structure at the first side CM1 and the encapsulation structure 90 at the second side CM2 may be differentially designed in the present disclosure, such that the encapsulation structure at the first side CM1 may be different from the encapsulation structure 90 at the second side CM2. For example, for the first side CM1 disposed with the connecting wire L0, if the connecting wire L0 is affected by external moisture, oxygen and the like, corrosion and other problems may occur to affect the reliability of signal transmission on the connecting wire L0. Therefore, the first side CM1 may have higher requirement for encapsulation, and the encapsulation structure with higher encapsulation reliability may be disposed at the position of the first side CM1. For the second side CM2 where the connecting wire L0 is not disposed, the encapsulation requirement may be lower than the encapsulation requirement of the first side CM1, so that there is no need to overprotect the second side CM2. While ensuring effective encapsulation of the second side CM2, unnecessary encapsulation film layers may be avoided to be disposed to simplify the encapsulation process of the second side CM2 and reduce the fabrication cost.

The differentiated design solution of the encapsulation structures of the first side CM1 and the second side CM2 is described hereinafter.

Referring to FIGS. 4 and 5, in an optional embodiment of the present disclosure, the encapsulation structures may include the first encapsulation structure 91 on the first side CM1 and the second encapsulation structure 92 on the second side CM2. The quantity of encapsulation layers included in the first encapsulation structure 91 may be greater than the quantity of encapsulation layers included in the second encapsulation structure 92. Referring to FIGS. 1-3, in one embodiment, the quantity of encapsulation layers included in the first encapsulation structure 91 may refer to the quantity of insulating layers disposed on the first side CM1 along the direction which is in parallel with the first surface S1 and the second surface S2, perpendicular to the side of the substrate 00 and points from the substrate 00 to the outside. The quantity of encapsulation layers included in the second encapsulation structure 92 may refer to the quantity of insulating layers disposed on the second side CM2 along the direction which is in parallel with the first surface S1 and the second surface S2, perpendicular to the side of the substrate 00 and points from the substrate 00 to the outside.

Optionally, the first encapsulation structure 91 of the first side CM1 and the second encapsulation structure 92 of the second side CM2 may both include at least one encapsulation layer, and at least the side of the array substrate 10 may be encapsulated by the encapsulation layer in the encapsulation structure. In one embodiment, the first encapsulation structure 91 and the second encapsulation structure 92 may be differentially designed by setting the quantity of encapsulation layers included in the first encapsulation structure 91 and the second encapsulation structure 92 to be different. For example, the quantity of encapsulation layers included in the first encapsulation structure 91 corresponding to the first side CM1 disposed with the connecting wire L0 may be greater than the quantity of encapsulation layers included in the second encapsulation structure 92 corresponding to the second side CM2 not disposed with the connecting wire L0. The region corresponding to the first side CM1 may be encapsulated using relatively large quantity of encapsulation layers, which may be more beneficial for isolating the connecting wire L0 of the first side CM1 from the outside, reducing or avoiding the influence of external moisture or oxygen on the connecting wire L0, and improving the encapsulation effect of the first side CM1 disposed with the connecting wire L0. For the second side CM2 where the connecting wire L0 is not disposed, in one embodiment, the quantity of encapsulation layers included in corresponding second encapsulation structure 92 may be reduced to be less than the quantity of encapsulation layers included in the first encapsulation structure 91, which may be beneficial for reducing the process of fabricating the encapsulation structure on the second side CM2 and saving the encapsulation materials needed for the second encapsulation structure 92, thereby being beneficial for simplifying overall fabrication process of the display panel and reducing fabrication cost.

Referring to FIGS. 4 and 5, in an optional embodiment of the present disclosure, the first encapsulation structure 91 may include M encapsulation layers stacked with each other, and the second encapsulation structure 92 may include N encapsulation layers stacked with each other, M−N≥1, M≥2, N≥1; that is, the quantity of encapsulation layers included in the first encapsulation structure 91 may be at least one more than the quantity of encapsulation layers included in the second encapsulation structure 92. For example, in one embodiment shown in FIG. 4, the first encapsulation structure 91 may include two encapsulation layers, and the second encapsulation structure 92 may include one encapsulation layer, which may be taken as an example for illustration and may not be limited in the present disclosure. In some other embodiments of the present disclosure, the quantity of encapsulation layers included in the first encapsulation structure 91 and the quantity of encapsulation layers included in the second encapsulation structure 92 may also be other numbers, and the difference in the quantity of encapsulation layers between above two encapsulation structures may also be other numbers.

FIG. 6 shows a top view of the array substrate 10 and the encapsulation structure on the side of the array substrate 10 according to various embodiments of the present disclosure. In one embodiment, the first side CM1 of the array substrate 10 may be disposed with two encapsulation layers (a wire encapsulation layer 21 and a filling encapsulation layer 22), the second side CM2 may be disposed with one encapsulation layer (the filling encapsulation layer 22), and the array substrate 10 may include one first side CM1 and three second side CM2, which may be taken as an example for illustration. When actually fabricating the encapsulation structure, one layer of encapsulation layer may be firstly fabricated on the first side CM1, and then another layer of encapsulation layer may be formed on the first side CM1 and the second side CM2, such that the first encapsulation structure 91 and the second encapsulation structure 92 may form a closed structure as a whole to completely encapsulate the side of the array substrate 10, thereby improving overall encapsulation performance of the display panel. It should be noted that after one encapsulation layer is formed on the first side CM1, another encapsulation layer may be formed on the first side CM1 and the second side CM2 by a unified process. That is, a part of the encapsulation layers in the first encapsulation structure 91 and the second encapsulation structure 92 may be fabricated in a same process, and there is no need to respectively introduce different encapsulation processes for the first side CM1 and the second side CM2, thereby being beneficial for simplifying the encapsulation process and improving overall fabrication efficiency of the display panel. It should be noted that the wire encapsulation layer 21 and the filling encapsulation layer 22 may be at least partially overlapped with each other, and there is no restriction on whether the filling encapsulation layer completely covers the wire encapsulation layer 21. To clearly describe relative positional relationship between the wire encapsulation 21 and the filling encapsulation layer 22, a part of the wire encapsulation layer 21 shown in FIG. 6 is not covered by the filling encapsulation layer 22.

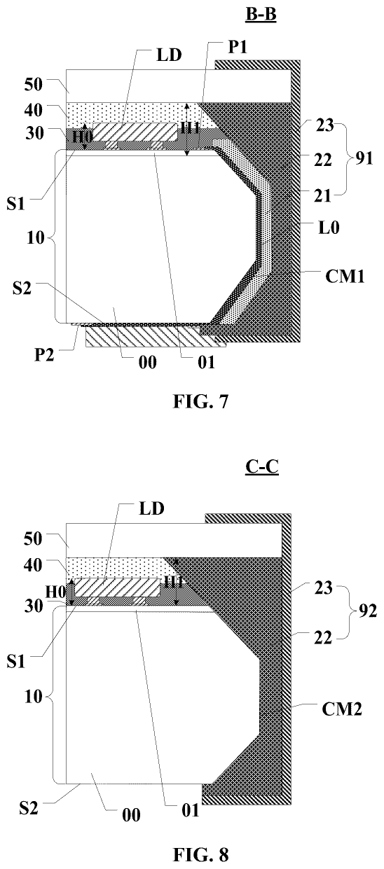

FIG. 7 illustrates another cross-sectional view of the display panel along the BB direction in FIG. 1. The difference from one embodiment in FIG. 4 is that the quantity of encapsulation layers included in the first encapsulation structure 91 may be different. FIG. 7 takes the first encapsulation structure 91 including three encapsulation layers as an example for explanation, and FIG. 4 takes the first encapsulation structure 91 including two encapsulation layers as an example for explanation. Compared with FIG. 4, in one embodiment shown in FIG. 7, the quantity of encapsulation layers included in the first encapsulation structure 91 may be increased, which may be beneficial for improving encapsulation reliability of the first side surface CM1 of the array substrate 10.

Referring to FIGS. 4 and 7, in an optional embodiment of the present disclosure, the first encapsulation structure 91 may include the wire encapsulation layer 21 and the filling encapsulation layer 22. On the side of the first side CM1 away from the array substrate 10, the wire encapsulation layer 21 may be in direct contact with the connecting wire L0 and the filling encapsulation layer 22, and at least a part of the wire encapsulation layer 21 may be between the connecting wire L0 and the filling encapsulation layer 22.

In the first encapsulation structure 91 provided in the present disclosure, the encapsulation layer directly contacting the connecting wire L0 on the first side CM1 may be the wire encapsulation layer 21. Optionally, the wire encapsulation layer 21 may be an insulating adhesive layer, which may have desirable adhesion to the connecting wire L0. The wire encapsulation layer 21 may reliably cover the connecting wire L0 and the first side CM1 to isolate the connecting wire L0 from outside moisture and oxygen. Optionally, the wire encapsulation layer 21 may be a black or gray light-blocking material, which may avoid or reduce the problem of light leakage on the side of the array substrate 10. In the present disclosure, the filling encapsulation layer 22 may be further disposed on the outside of the wire encapsulation layer 21. On the side of the first side CM1, the surface of the wire encapsulation layer 21 facing toward the first side CM1 may be in direct contact with the connecting wire L0, and the surface of the wire encapsulation layer 21 away from the first side CM1 may be in direct contact with the filling encapsulation layer 22, which may be equivalent to further encapsulating the wire encapsulation layer 21 with the filling encapsulation layer 22. The double encapsulation of the wire encapsulation layer 21 and the filling encapsulation layer 22 may be more beneficial for improving encapsulation reliability of the first side CM1. Optionally, the filling encapsulation layer 22 may also be embodied as a black or gray material with a light-absorbing effect.

FIG. 8 illustrates another cross-sectional view of the display panel along the CC direction in FIG. 1. The difference from one embodiment in FIG. 5 is that the quantity of encapsulation layers included in the second encapsulation structure 92 may be different. In FIG. 5, the first encapsulation structure 91 may exemplarily include one encapsulation layer for illustration; and in FIG. 8, the first encapsulation structure 91 may exemplarily include two encapsulation layers for illustration. Compared with FIG. 5, in one embodiment shown in FIG. 8, the quantity of encapsulation layers included in the second encapsulation structure 92 may be increased, which may be more beneficial for improving encapsulation reliability of the second side CM2 of the array substrate 10.

Referring to FIGS. 5 and 8, in an optional embodiment of the present disclosure, the second encapsulation structure 92 may include the filling encapsulation layer 22. On the side of the second side CM2 away from the array substrate 10, the filling encapsulation layer 22 may be in direct contact with the second side CM2. For the second side CM2 where the connecting wire L0 is not disposed, in the present disclosure, the wire encapsulation layer 21 may be not disposed; and the filling encapsulation layer 22 may be in direct contact with the second side CM2, which may be equivalent to eliminating the process and materials for fabricating the wire encapsulation layer 21 on the second side CM2, thereby being beneficial for improving the encapsulation fabrication efficiency and reducing the fabrication cost. Optionally, the filling encapsulation layer 22 on the second side CM2 and the filling encapsulation layer 22 on the first side CM1 may be made of a same material using a same process; and there is no need to respectively introduce the fabrication processes of the filling encapsulation layer 22 for the first side CM1 and the second side CM2, which may be beneficial for further simplifying the fabrication process of the display panel. In actual fabrication, the wire encapsulation layer 21 may be first disposed on the first side CM1 but not disposed on the second side CM2. The first side CM1 may be first encapsulated using the wire encapsulation layer 21, and the filling encapsulation layer 22 may be formed on the first side CM1 and the second side CM2. The filling encapsulation layer 22 of the first side CM1 and the second side CM2 may be made of a same material using a same process. Optionally, the wire encapsulation layer 21 and the filling encapsulation layer 22 may be embodied as black or gray materials with light-absorbing effect.

Referring to FIGS. 1, 2, 4 and 7, when the wire encapsulation layer 21 is disposed on the first side CM1 in embodiments of the present disclosure, the wire encapsulation layer 21 may be not only on the first side CM1 but also may extend from the first side CM1 to the first surface S1 and the second surface S2. In such way, the wire encapsulation layer 21 may encapsulate the connecting wire L0 on the first side surface CM1 and may also encapsulate at least a part of the connecting wire L0 on the first surface S1 and the second surface S2. Continuous wire encapsulation layer 21 may be formed on the first surface S1, the first side surface CM1 and the second surface S2, which may be beneficial for preventing moisture and oxygen from penetrating into the array substrate 10 from the connection position between the first surface S1 and the first side surface CM1, and the connection position between the second surface S2 and the first side surface CM1.

Referring to FIGS. 3, 7 and 8, in an optional embodiment of the present disclosure, the display panel may further include the light-emitting element LD electrically connected to the array substrate 10 and on the first surface S1. An electrode configured to be electrically connected to the light-emitting element LD may be disposed on the first surface S1 of the array substrate 10. The light-emitting element LD may be bound to the electrode and then electrically connected to the circuit in the array substrate 10. At least a part of the filling encapsulation layer 22 may be on the side of the first surface S1 away from the second surface S2. The distance between the second surface S2 and the surface of the light-emitting element LD away from the first surface S1 is H0, and the distance between the second surface S2 and the surface of the filling encapsulation layer 22 away from the first surface S1 is H1, where H1>H0.

In one embodiment, relative positional relationship between the first encapsulation structure 91 and other film layers in the display panel is illustrated. In addition to being disposed on the side of the first side surface CM1 and the second side surface CM2, the filling encapsulation layer 22 may further extend to the side of the first surface S1 of the array substrate 10 away from the second surface S2. In one embodiment, the upper surface of the filling encapsulation layer 22 on the side of the first surface S1 away from the second surface S2 may be higher than the upper surface of the light-emitting element LD. That is, the distance H1 between the upper surface of the filling encapsulation layer 22 (the surface away from the first surface S1 and in parallel with the first surface S1) and the first surface S1 may be greater than the distance H0 between the upper surface of the light-emitting element LD (the surface away from the first surface S1) and the first surface S1, which may be equivalent to increasing total height of the filling encapsulation layer 22 along the direction perpendicular to the first surface S1. In such way, the encapsulation area of the filling encapsulation layer 22 on the side of the display panel may be increased, thereby being beneficial for improving the encapsulation effect of the filling encapsulation layer 22 on the side of the display panel. Optionally, the filling encapsulation layer 22 corresponding to the first side surface CM1 and the filling encapsulation layer 22 corresponding to the second side surface CM2 may have same relative positional relationship with the height of the light-emitting element LD; that is, total height of the filling encapsulation layer 22 located in different regions of the display panel along the direction perpendicular to the first surface S1 may be consistent, which may be beneficial for simplifying the fabrication process.

Referring to FIGS. 7-8, in an optional embodiment of the present disclosure, the display panel may further includes a first light-blocking layer 30 and a light-transmitting layer 40 on the first surface S1; the first light-blocking layer 30 may be at least partially between adjacent light-emitting elements LD; the light-transmitting layer 40 may be on the side of the first light-blocking layer 30 away from the first surface S1 and cover the light-emitting element LD and at least a part of the first light-blocking layer 30; and the filling encapsulation layer 22 may be in contact with the side surfaces of the first light-blocking layer 30 and the light-transmitting layer 40.

The first light-blocking layer 30 disposed in the display panel of one embodiment may be configured to block the metal film layer on the array substrate 10 to avoid the problem of metal reflection. It should be noted that the first light-blocking layer 30 may be located not only at the region between adjacent light-emitting elements LD, but also directly below the light-emitting element LD to cover the electrode of the light-emitting element LD which may avoid the problem of metal reflection of the electrode of the light-emitting element LD. When the first light-blocking layer 30 is disposed, the first light-blocking layer 30 may not cover the upper surface of the light-emitting element LD to avoid affecting the light output of the light-emitting element LD. The upper surface of the first light-blocking layer 30 may be lower than the upper surface of the light-emitting element LD, or the upper surface of the first light-blocking layer 30 may be coplanar with the upper surface of the light-emitting element LD. In the display panel, the light-transmitting layer 40 may be disposed on the side of the light-emitting element LD and the first light-blocking layer 30 away from the first surface S1. The light-transmitting layer 40 may be configured to encapsulate the light-emitting element LD to prevent moisture and oxygen from entering and form a flat surface on the side of the light-emitting element LD away from the first surface S1. When the height of the upper surface of the filling encapsulation layer 22 is greater than the height of the upper surface of the light-emitting element LD, the filling encapsulation layer 22 may be in contact with the side surfaces of the first light-blocking layer 30 and the light-transmitting layer 40 respectively, and may cover the side boundary region of the first light-blocking layer 30 and the light-transmitting layer 40, which may prevent external moisture and oxygen from penetrating from the boundary region between the first light-blocking layer 30 and the light-transmitting layer 40, thereby being beneficial for the encapsulation effect of the filling encapsulation layer 22 on entire display panel.

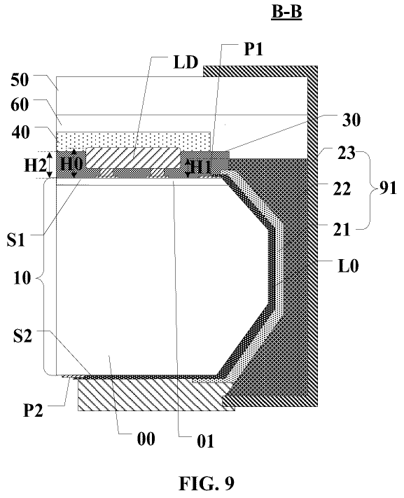

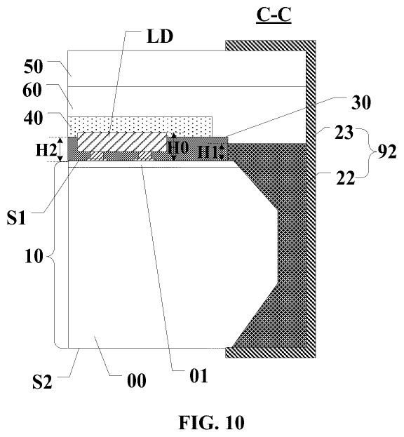

Above-mentioned embodiment describes a solution that the upper surface of the filling encapsulation layer 22 is higher than the upper surface of the light-emitting element LD. In some other embodiments of the present disclosure, the upper surface of the filling encapsulation layer 22 may also be coplanar with the upper surface of the light-emitting element LD or lower than the upper surface of the light-emitting element LD. FIG. 9 illustrates another cross-sectional view of the display panel along the BB direction in FIG. 1; and FIG. 10 illustrates another cross-sectional view of the display panel along the CC direction in FIG. 1. Referring to FIGS. 9-10, in an optional embodiment of the present disclosure, the display panel may further include the first light-blocking layer 30 and the light-emitting element LD electrically connected to the array substrate 10 and on the first surface S1, where the first light-blocking layer 30 may be at least partially between adjacent light-emitting elements LD; the distance between the second surface S2 and the surface of the light-emitting element LD away from the first surface S1 is H0, the distance between the second surface S2 and the surface 2 of the first light-blocking layer 30 away from the first surface S1 is H2, and the distance between the second surface S2 and the surface of the filling encapsulation layer 22 away from the first surface S1 is H1, where H0≥H2≥H1.

In one embodiment, the first light-blocking layer 30 disposed in the display panel may be configured to block the metal film layer on the array substrate 10 to avoid the problem of metal reflection. It should be noted that the first light-blocking layer 30 may be located not only at the region between adjacent light-emitting elements LD, but also directly below the light-emitting element LD to cover the electrode of the light-emitting element LD, which may avoid the problem of metal reflection of the electrode of the light-emitting element LD. When the first light-blocking layer 30 is disposed, the first light-blocking layer 30 may not cover the upper surface of the light-emitting element LD, which may avoid affecting the light output of the light-emitting element LD. In one embodiment, the height relationship between the light-emitting element LD, the first light-blocking layer 30 and the filling encapsulation layer 22 is that the upper surface of the light-emitting element LD may be higher than or coplanar with the upper surface of the first light-blocking layer 30, and the upper surface of the first light-blocking layer 30 may be higher than or coplanar with the upper surface of the filling encapsulation layer 22. In one embodiment, the upper surface of the first light-blocking layer 30 may be configured not to exceed the upper surface of the light-emitting element LD, which may be beneficial for preventing the first light-blocking layer 30 from affecting forward light emission of the light-emitting element LD. In actual fabrication, the filling encapsulation layer may be formed after the first light-blocking layer 30 is formed. When the upper surface of the encapsulation filling layer does not exceed the upper surface of the first light-blocking layer 30, the first light-blocking layer 30 may be configured as a positioning reference for forming the filling encapsulation layer 22, which may be beneficial for simplifying the fabrication difficulty of the filling encapsulation layer 22 and simplifying overall fabrication process of the display panel.

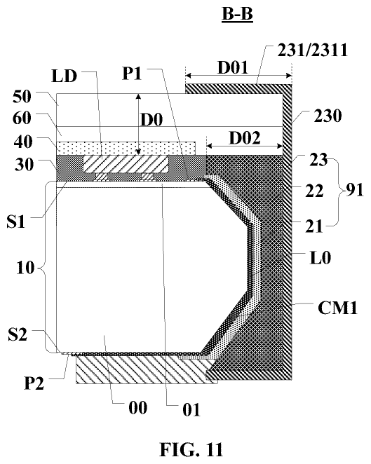

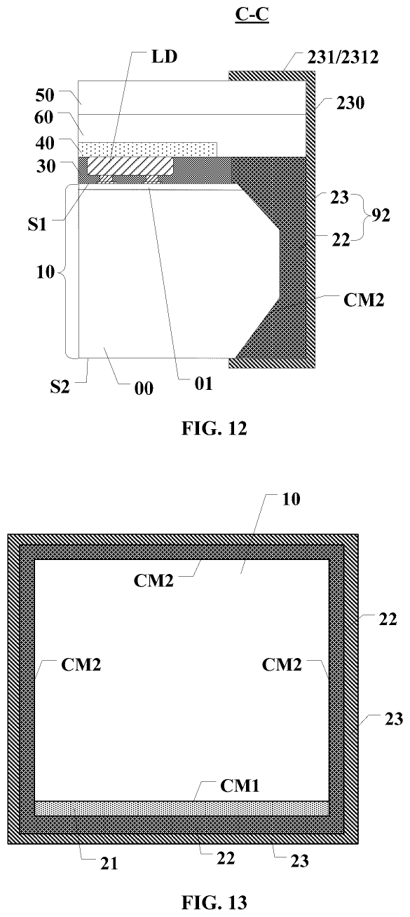

It should be noted that in some other embodiments of the present disclosure, the height of the upper surface of the filling encapsulation layer 22 may also be coplanar with the height of the upper surface of the light-emitting element LD. For example, referring to FIGS. 11-12, FIG. 11 illustrates another cross-sectional view of the display panel along the BB direction in FIG. 1; and FIG. 12 illustrates another cross-sectional view of the display panel along the CC direction in FIG. 1. At this point, the upper surface of the light-emitting element LD, the upper surface of the first light-blocking layer 30, and the upper surface of the filling encapsulation layer 22 may be arranged on a same plane, and the first light-blocking layer 30 may also be configured as a positioning reference when forming the filling encapsulation layer 22, which may simplify the fabrication difficulty of the filling encapsulation layer 22.

Referring to FIGS. 9-12, in an optional embodiment of the present disclosure, the display panel may further include the light-transmitting layer 40. The light-transmitting layer 40 may be on the side of the first light-blocking layer 30 away from the first surface S1 and cover the light-emitting element LD and at least a part of the first light-blocking layer 30; the filling encapsulation layer 22 may be in contact with the side of the first light-blocking layer 30.

In one embodiment, the light-transmitting layer 40 may be disposed on the side of the light-emitting element LD away from the first surface S1; and the light-transmitting layer 40 may cover the light-emitting element LD. The light-transmitting layer may be configured to encapsulate the light-emitting element LD to prevent external moisture and oxygen from affecting the light-emitting element LD. Meanwhile, the light-transmitting layer 40 may also cover at least a part of the first light-blocking layer 30. The upper surface of the filling encapsulation layer 22 may not exceed the upper surface of the first light-blocking layer 30; that is, the filling encapsulation layer 22 may be not in contact with the side of the light-transmitting layer 40. At this point, a transparent adhesive layer 60 may be disposed on the side of the light-transmitting layer 40 and the filling encapsulation layer 22 away from the array substrate 10, such that the transparent adhesive layer 60 may cover the upper surfaces of the light-transmitting layer 40, the first light-blocking layer 30 and the filling encapsulation layer 22, which may realize the encapsulation and fixation of above-mentioned film layers. Meanwhile, the surface of the transparent adhesive layer 60 away from the array substrate 10 may form a flat surface, which may realize seamless bonding (attachment) with the cover plate or other film materials.

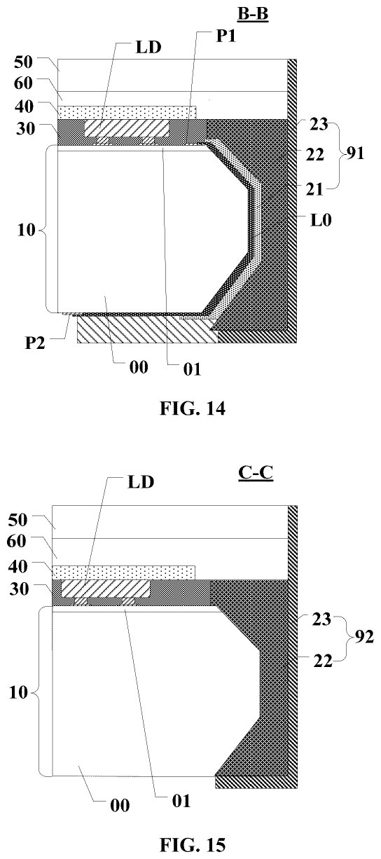

FIG. 13 illustrates another top view of the array substrate 10 and the encapsulation structure on the side of the array substrate 10 according to various embodiments of the present disclosure; FIG. 14 illustrates another cross-sectional view of the display panel along the BB direction in FIG. 1; and FIG. 15 illustrates another cross-sectional view of the display panel along the CC direction in FIG. 1. Referring to FIGS. 11-15, the coverage of the light-blocking encapsulation layer 23 in the solution shown in FIGS. 11-12 may be different from the coverage of the light-blocking encapsulation layer 23 in the solution shown in FIGS. 14-15. In an optional embodiment of the present disclosure, the first encapsulation structure 91 and the second encapsulation structure 92 may include the light-blocking encapsulation layer 23, and the light-blocking encapsulation layer 23 may be at least partially on the side of the filling encapsulation layer 22 away from the first side surface.

In one embodiment, it describes the solution that the encapsulation structure may further include the light-blocking encapsulation layer 23 which may be at least on the periphery of the side of the filling encapsulation layer 22. Optionally, the light-blocking encapsulation layer 23 may be a black material or a material with high light absorption or high grayscale. On the one hand, the light-blocking encapsulation layer 23 may prevent the light from leaking sideways from the display panel. On the other hand, the light-blocking encapsulation layer 23 may also be configured as the encapsulation layer to improve encapsulation reliability of the display panel and configured as the first line of defense to prevent moisture and oxygen from entering the side of the display panel. In the solution shown in FIGS. 11-12, the light-blocking encapsulation layer 23 may extend from the side surface (the first side surface) to the front of the display panel. In the solution shown in FIGS. 14-15, the light-blocking encapsulation layer 23 may not extend to the front of the display panel. Both above solutions may realize side (sideway) encapsulation of the display panel and block side (sideway) light leakage.

Referring to FIGS. 11-12, in an optional embodiment of the present disclosure, the display panel may further include the first light-blocking layer 30 and the light-emitting element LD electrically connected to the array substrate 10 and on the first surface S1, and the first light-blocking layer 30 may be at least partially between adjacent light-emitting elements LD; the light-blocking encapsulation layer 23 may include a main body portion and a first extension portion 231 connected to the main body portion, the main body portion may be on the side of the filling encapsulation layer away from the first side surface, the first extension portion 231 may be on the light-exiting side of the light-emitting element LD, and the first extension portion 231 may be not overlapped with the light-emitting element LD along the direction perpendicular to the plane of the array substrate 10.

In one embodiment, it describes the solution that the light-blocking encapsulation layer 23 may be not only on the side of the display panel (including the side of the array substrate 10) but also extend from the side surface (the first side surface) of the display panel to the front (the light-exiting surface) of the display panel. The portion of the light-blocking encapsulation layer 23 on the side of the display panel may be the main body portion, the portion extending to the front of the display panel may be the first extension portion 231, and the main body portion and the first extension portion 231 may be seamlessly connected. When the light-blocking encapsulation layer 23 is disposed only on the side of the display panel, if the side of the display panel is a vertical surface or a steep surface similar to the vertical surface relative to the light-exiting surface of the display surface, when the light-blocking encapsulation layer 23 is formed on the vertical surface or the steep surface, adhesion reliability of the light-blocking encapsulation layer 23 may be not high, and there is a risk of peeling off from the side of the display panel, which may affect overall encapsulation reliability of the display panel. Therefore, when the light-blocking encapsulation layer 23 is extended to the front of the display panel to form the first extension portion 231 on the front, the first extension portion 231 may have relatively high adhesion to the front of the display panel, and the first extension portion 231 may be connected to the main body portion 230, which may fix the first extension portion 231 and prevent the first extension portion 231 from peeling off from the side of the display panel, thereby being beneficial for improving fixing reliability and encapsulation reliability of the light-blocking encapsulation layer 23. In addition, when the front of the display panel is disposed with the first extension portion 231 of the light-blocking encapsulation layer 23, the first extension portion 231 may not extend directly above the light-emitting element LD; that is, along the direction perpendicular to the plane of the array substrate 10, the first extension portion 231 and the light-emitting element LD may be not overlapped with each other, which may be beneficial for avoiding the first extension portion 231 from affecting forward light emission of the light-emitting element LD.

Referring to FIGS. 11-12, in an optional embodiment of the present disclosure, along the direction perpendicular to the plane of the array substrate 10, the distance D0 between the surface of the light-emitting element LD away from the array substrate 10 and the first extension portion 231 may be greater than 0. At this point, the distance between the surface of the first extension portion 231 away from the array substrate 10 and the first surface S1 of the array substrate 10 may be greater than the distance between the surface of the light-emitting element LD away from the array substrate 10 and the first surface S1 of the array substrate 10. Taking FIG. 11 as an example, at least two insulating film layers may be spaced between the upper surface of the light-emitting element LD and the first extension portion 231, such that it may be beneficial for increasing the height of the first extension portion 231 in the light-blocking encapsulation layer 23. The main body portion of the light-blocking encapsulation layer 23 may encapsulate and cover the side surfaces of all film layers above the upper surface of the light-emitting element LD, which may avoid side light leakage of the display panel and ensure the reliability of the encapsulation effect.

Referring to FIG. 11, in an optional embodiment of the present disclosure, the first extension portion 231 may be overlapped with the first soldering pad P1 along the direction perpendicular to the plane of the array substrate 10. Optionally, the first extension portion 231 may cover the first soldering pad P1. In the display panel, the first soldering pad P1 may be disposed at the first surface S1 of the array substrate 10 and on the side of the light-emitting element LD facing toward the first side surface CM1. The first soldering pad P1 may be a metal pad. When the first soldering pad P1 is fully or partially covered by the first extension portion 231 along the direction perpendicular to the plane of the array substrate 10, the edge of the display panel may also be blackened to prevent light leakage from the edge of the display panel.

Referring to FIGS. 11-12, in an optional embodiment of the present disclosure, the first extension portion 231 may be overlapped with the first light-blocking layer 30 along the direction perpendicular to the plane of the array substrate 10. The first light-blocking layer 30 may be at least between adjacent light-emitting elements LD and directly below the light-emitting element LD. The first light-blocking layer 30 may be also disposed on the side of the light-emitting element LD facing toward the first side CM1 and the second side CM2 of the array substrate 10. Such portion of the first light-blocking layer 30 may be at least partially overlapped with the first soldering pad P1 to block the soldering pad from reflecting light. When the first extension portion 231 is disposed on the front of the display panel and the first extension portion 231 is overlapped with the first light-blocking layer 30, the first extension portion 231 and the first light-blocking layer 30 may form a light-blocking structure as a whole on the side of the light-emitting element LD facing toward the first side surface CM1 of the array substrate 10, which may effectively block the edge region of the display panel and avoid the problem of edge light leakage or visible edge metal of the display panel.

Referring to FIG. 11, in an optional embodiment of the present disclosure, along the direction of the first surface S1 pointing to the first side surface, the width of the first extension portion 231 is D01, and the width of the filling encapsulation layer 22 is D02, where D01≥D02.

In one embodiment, on the front of the display panel, the extension width of the first extension portion 231 may be greater than the extension width of the filling encapsulation layer 22. In some other embodiments of the present disclosure, the extension width of the first extension portion 231 may also be equal to the extension width of the filling encapsulation layer 22, which may not be limited in the present disclosure. The light-blocking encapsulation layer 23 may be at the outermost part of the display panel; and along the direction perpendicular to the plane of the array substrate 10, the filling encapsulation layer 22 and the first extension portion 231 of the light-blocking encapsulation layer 23 may be isolated by other transparent insulating film layers. If the extension width of the filling encapsulation layer 22 is greater than the extension width of the first extension portion 231 on the front of the display panel, the filling encapsulation layer 22 may be exposed outside the first extension portion 231. If the filling encapsulation layer 22 and the first light-blocking layer 30 are made of different materials, the black state (off state) effect at the edge region of the display panel may be inconsistent, which may affect the black state uniformity of the edge region of the display panel. Therefore, on the front of the display panel, when the width of the first extension portion 231 is configured to be greater than the width of the filling encapsulation layer 22, the first extension portion 231 may cover the filling encapsulation layer 22, thereby being beneficial for ensuring the consistency of the black state effect at the edge of the display panel.

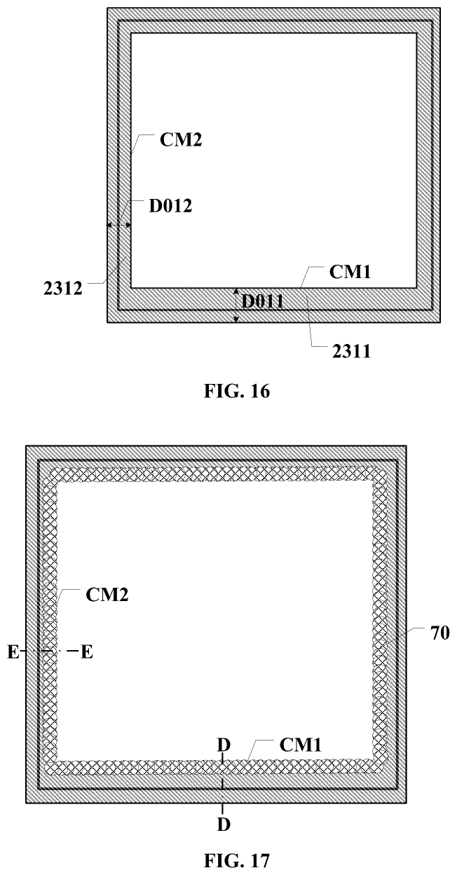

FIG. 16 illustrates a schematic of relative position relationship between the first extension portion 231 and the front of the display panel according to various embodiments of the present disclosure. Referring to FIGS. 11, 12 and 16, in an optional embodiment of the present disclosure, the first extension portion 231 may include a first sub-extension portion 2311 corresponding to the first encapsulation structure 91 and a second sub-extension portion 2312 corresponding to the second encapsulation structure 92; and along the direction of the first surface S1 pointing to the first side surface, the width of the first sub-extension portion is D011, and along the direction of the first surface S1 pointing to the second side surface, the width of the second sub-extension portion is D012, where D011>D012.

In one embodiment, the display panel including one first side surface CM1 and three second side surfaces CM2 is taken as an example for illustration. The first extension portion 231 extending from the first side surface CM1 to the front of the display panel may be the first sub-extension portion 2311, and the first extension portion 231 extending from the second side surface CM2 to the front of the display panel may be the second sub-extension portion 2312. Considering that in the first surface S1 of the array substrate 10, the region adjacent to the first side surface CM1 is disposed with the first soldering pad P1, while the region adjacent to the second side surface CM2 is not disposed with the soldering pad, the width of the first sub-extension 2311 and the width of the second sub-extension 2312 may be designed differently, such that the width of the first sub-extension 2311 may be greater than the width of the second sub-extension 2312, thereby ensuring that the first sub-extension 2311 may fully cover the first soldering pad P1 to avoid the problem of metal reflection. Meanwhile, the width of the second sub-extension 2312 may be reduced, which may be also beneficial for saving material usage and fabrication cost.

Obviously, in some other embodiments of the present disclosure, the widths of the first sub-extension portion 2311 and the second sub-extension portion 2312 may also be configured to be same, which may improve the uniformity of coverage of the light-blocking encapsulation layer 23 in the edge region of the display panel.

In an optional embodiment of the present disclosure, along the direction of the first surface S1 pointing to the first side surface, the width of the first extension portion 231 is D01, and 0<D01≤100 μm. If the width of the first extension portion 231 is configured to be relatively large, the display panel may not achieve extremely narrow frame or frameless design, so that the width of the first extension portion 231 may need to be reduced to be small as possible. When the width of the first extension portion 231 is configured to not more than 100 μm in the present disclosure, it is difficult for the human eye to perceive the width of the first extension portion 231, thereby being beneficial for achieving extremely narrow frame or frameless design of the display panel.

Referring to FIGS. 11-12, in an optional embodiment of the present disclosure, the first extension portion 231 and the main body portion 230 in the light-blocking encapsulation layer 23 may be formed into a single piece. The first extension portion 231 and the main body portion 230 may be made of a same material using a same fabrication process; and there is no need to use different fabrication processes and materials for the first extension portion 231 and the main body portion 230, which may be beneficial for simplifying the fabrication process of the light-blocking encapsulation layer 23. In addition, when the first extension portion 231 and the main body portion 230 are formed into a single piece, the adhesion force between the first extension portion 231 and the front of the display panel may be stronger, and the first extension portion 231 may play a certain pulling role on the main body portion, thereby avoiding the problem that the main body portion is peeled off from the side of the display panel to affect encapsulation reliability of the display panel.

Referring to FIGS. 7, 8, 11 and 12, in an optional embodiment of the present disclosure, the distance between the first extension portion 231 and the filling encapsulation layer 22 along the direction perpendicular to the plane of the array substrate 10 may be greater than 0. On the front of the display panel, at least one other insulating film layer may be disposed between the first extension portion 231 and the filling encapsulation layer 22; for example, the first protection layer 50 (for example, which may be embodied as a transparent cover plate) may be disposed, or the first protection layer 50 and the transparent adhesive layer 60 may be disposed. That is, on the front of the display panel, the film layers disposed on the side of the light-emitting element LD away from the array substrate 10 may be all below the first extension portion 231; and the main body portion of the light-blocking encapsulation layer 23 may fully cover the side of the filling encapsulation layer 22 and the side of the film layer between the filling encapsulation layer 22 and the first light-blocking layer 30, which may be beneficial for improving overall encapsulation effect and light-blocking effect of the light-blocking encapsulation layer 23 on the side of the display panel.

Optionally, referring to FIGS. 7, 8, 11 and 12, the display panel may further include the light-transmitting layer 40 and the first protection layer 50; the light-transmitting layer 40 may be on the side of the first light-blocking layer 30 and the light-emitting element LD away from the first surface S1; the first protection layer 50 may be on the side of the light-transmitting layer 40 away from the first surface S1; the first extension portion 231 may be on the surface of the first protection layer 50 away from the light-transmitting layer 40; and the filling encapsulation layer 22 may be on the side of the first protection layer 50 facing toward the array substrate 10.

Optionally, the light-transmitting layer 40 may be embodied as, for example, a transparent adhesive layer, which may be configured to encapsulate the front of the light-emitting element LD to prevent external moisture and oxygen from affecting the light-emitting element LD; and the surface of the light-transmitting layer 40 away from the array substrate 10 may be a flat surface. The first protection layer 50 may be, for example, a transparent cover of the display panel. In the encapsulation structure of embodiments of the present disclosure, along the direction perpendicular to the plane of the array substrate 10, the first extension portion 231 in the light-blocking encapsulation layer 23 may be on the upper surface of the first protection layer 50. That is, the light-blocking encapsulation layer 23 may extend from the side surface of the display panel to the upper surface of the display panel, and the light-blocking encapsulation layer 23 on the side of the display panel may fully cover the side of the array substrate 10, the side of the light-transmitting layer 40, and the side of the first protection layer 50, which may increase the coverage region of the light-blocking encapsulation layer 23, thereby being beneficial for improving the light-blocking reliability of the light-blocking encapsulation layer 23 on the side of the display panel, preventing side light leakage of the display panel and improving encapsulation reliability of overall side of the display panel.

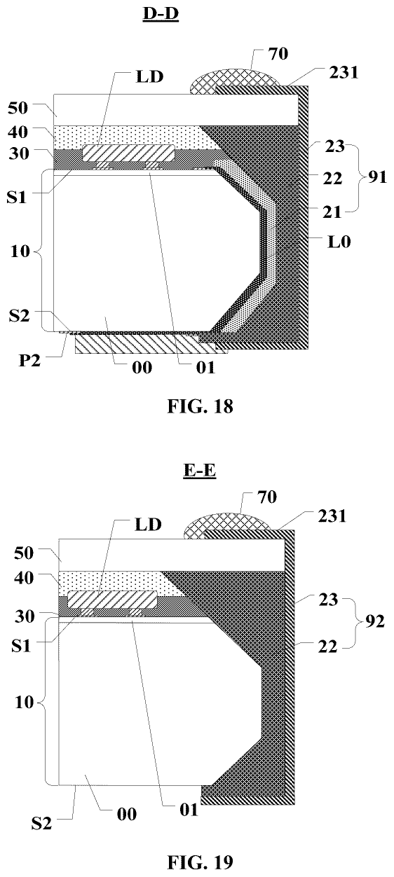

FIG. 17 illustrates another schematic of relative position relationship between the first extension portion 231 and the front of the display panel according to various embodiments of the present disclosure; FIG. 18 illustrates a cross-sectional view of the display panel along a DD direction in FIG. 17; and FIG. 19 illustrates a cross-sectional view of the display panel along an EE direction in FIG. 17. Referring to FIGS. 17-19, in an optional embodiment of the present disclosure, the display panel may further include an encapsulation protection layer 70. On the side of the first surface S1 away from the second surface S2, the encapsulation protection layer 70 may be on the side of the first extension portion 231 and the first protection layer 50 away from the first surface S1; and along the direction perpendicular to the plane of the array substrate 10, the encapsulation protection layer 70 may be at least overlapped with the edge of the first extension portion 231.

In one embodiment, it describes the solution of disposing the encapsulation protection layer 70 into the display panel. In actual fabrication, after the light-blocking encapsulation layer 23 is fabricated, the encapsulation protection layer 70 may be fabricated on the front of the display panel, such that the encapsulation protection layer 70 may cover at least a part of the first extension portion 231 and be overlapped with the edge of the first extension portion 231. The edge of the first extension portion 231 refers to the edge of the first extension portion 231 away from the main body portion. Along the direction perpendicular to the plane of the array substrate 10, the encapsulation protection layer 70 may be not overlapped with the light-emitting element LD, which may avoid affecting forward light emission of the light-emitting element LD. When the light-blocking encapsulation layer 23 includes the first extension portion 231 on the front of the display panel, in order to achieve extremely narrow frame or frameless design of the display panel, the width of the first extension portion 231 may be designed to be relatively small, so that the edge of the first extension portion 231 may be very likely to be warped, which may affect visual effect. Therefore, in one embodiment, the encapsulation protection layer 70 may be disposed on the side of the first extension portion 231 away from the substrate 00, and the encapsulation protection layer 70 may be at least overlapped with the edge of the first extension portion 231. The encapsulation protection layer 70 may fix the edge of the first extension portion 231 to prevent the edge of the first extension portion 231 from warping. It should be noted that the adhesion force of the encapsulation protection layer 70 may be greater than the adhesion force of the first extension portion 231, a part of the encapsulation protection layer 70 may be in direct contact with the first protection layer 50, and a part of the encapsulation protection layer 70 may be in direct contact with the edge of the first extension portion 231, and the edge of the first extension portion 231 may be reliably fixed by strong adhesion effect. Optionally, the encapsulation protection layer 70 may include a black light-blocking material.

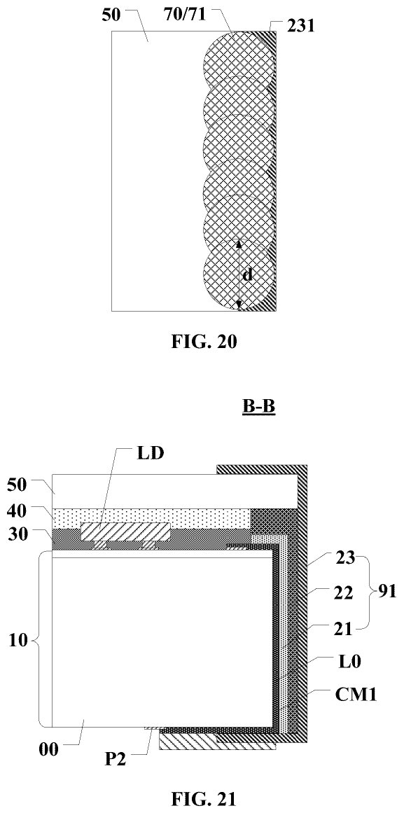

FIG. 20 illustrates a schematic of relative position relationship the encapsulation protection layer 70, the first extension portion 231, and the first protection layer 50. Referring to FIG. 20, in an optional embodiment of the present disclosure, the encapsulation protection layer 70 may include a plurality of microstructures 71 arranged along the edge of the first extension portion 231, and the projection of the microstructure 71 on the first surface S1 may include an arc edge. The microstructure 71 of the encapsulation protection layer 70 may be regarded as a dot-shaped structure. The plurality of dot-shaped structures may be densely arranged along the edge of the first extension portion 231 to form a uniform wave-like structure on the side of the edge of the first extension portion 231 away from the side surface of the display panel, such that the edge of the encapsulation protection layer 70 toward the center of the display panel may be more symmetrical, which may be beneficial for reducing abruptness of visual effect of the boundary of the display panel.

Referring to FIGS. 18-19, in an optional embodiment of the present disclosure, along the direction perpendicular to the plane of the array substrate 10, the projection of the microstructure 71 on the first surface S1 may cover at least a part of the side surface of the first extension portion 231. In such way, it is equivalent to covering the edge of the first extension portion 231 with the microstructure 71 and making the microstructure 71 directly contact the side surface of the first extension portion 231, which may be beneficial for increasing the contact area between the microstructure 71 and the side surface of the first extension portion 231 and beneficial for improving the fixing reliability of the microstructure 71 to the edge of the first extension portion 231, thereby further being beneficial for avoiding the warping problem of the edge of the first extension portion 231.

Referring to FIG. 20, in an optional embodiment of the present disclosure, the projections of adjacent microstructures 71 may be overlapped with each other along the direction perpendicular to the plane of the array substrate 10. The projection of the microstructure 71 on the plane of the array substrate 10 may be a circle with same diameter, which is taken as an example for illustration. When the projections of adjacent microstructures 71 are overlapped with each other, the distance between the centers of two adjacent circular microstructures 71 may be less than the diameter of a single microstructure 71. At this point, adjacent microstructures 71 may be closely arranged, which may improve the fixing reliability of the microstructures 71 to the edge of the first extension portion 231.

In an optional embodiment of the present disclosure, the diameter of the microstructure 71 may be 1 μm≤d≤100 μm. If the diameter of the microstructure 71 is configured to be relatively small, for example, less than 1 μm, the microstructure 71 may not be sufficient to be in direct contact with the upper surface of the first extension portion 231, the side of the first extension portion 231 and part of the first protection layer 50 simultaneously, which may affect the fixing reliability of the microstructure 71 to the first extension portion 231. Therefore, in one embodiment, when the diameter of the microstructure 71 is configured to be greater than or equal to 1 μm, at least a part of the microstructure 71 may be in direct contact with the upper surface of the first extension portion 231, a part of the microstructure 71 may be in direct contact with the side of the first extension portion 231, and a part of the microstructure 71 may be in direct contact with the first protection layer 50 on the side of the first extension portion 231, thereby being beneficial for improving the fixing reliability of the microstructure 71 to the edge of the first extension portion 231 and preventing the edge of the first extension portion 231 from warping. In addition, the width of the first extension portion 231 may be less than or equal to 100 μm. When the diameter of the microstructure 71 is configured to be less than or equal to 100 μm, the microstructure 71 may be controlled to be in direct contact with the upper surface and side surface of the first extension portion 231 and at least a part of the first protection layer 50 when the microstructure 71 is formed, which may avoid the diameter of the microstructure 71 being too large and exceeding the size of the first extension portion 231 to affect the design of the narrow frame or extremely narrow frame of the display panel.

Optionally, the diameter of the microstructure 71 may be 10 μm≤d≤90 μm, or 20 μm≤d≤80 μm, or 30 μm≤d≤60 μm, or 40 μm≤d≤50 μm, which may be not limited in the present disclosure.

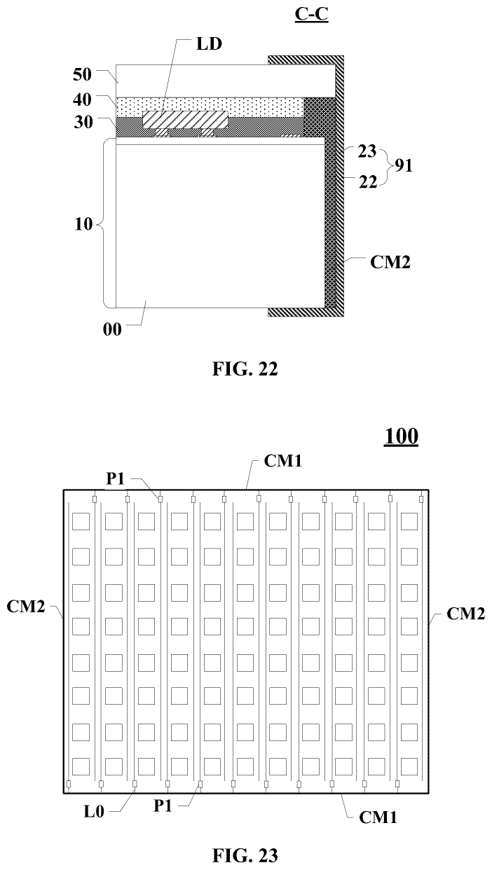

FIG. 21 illustrates another cross-sectional view of the display panel along the BB direction in FIG. 1; and FIG. 22 illustrates another cross-sectional view of the display panel along the CC direction in FIG. 1. Referring to FIGS. 21-22, in an optional embodiment of the present disclosure, at least one of the first side surface CM1 and the second side surface CM2 may be perpendicular to the second surface S2. That is, the first side surface CM1 and the second side surface CM2 of the array substrate 10 may be planar structures perpendicular to the first surface S1 of the array substrate 10. In such way, the first side surface CM1 and the second side surface CM2 may be formed by existing cutting manner, which may be beneficial for simplifying the fabrication process of the display panel.

Referring to FIGS. 4-5, in an optional embodiment of the present disclosure, at least one of the first side surface CM1 and the second side surface CM2 may include the first sub-side surface 81, the second sub-side surface 82, and the first connecting surface 83 configured to connect the first sub-side surface 81 and the second sub-side surface 82, where the first sub-side surface 81 may be connected to the first surface S1, the second sub-side surface 82 may be connected to the second surface S2, the angle between the first sub-side surface 81 and the first surface S1 may be an obtuse angle, the angle between the second sub-side surface 82 and the second surface S2 may be an obtuse angle, and the first connecting surface 83 may be perpendicular to the light-exiting surface of the display panel.

In one embodiment, it describes the solution that the first side surface CM1 and the second side surface CM2 of the array substrate 10 are non-planar structures. The first side surface CM1 and the second side surface CM2 may both include the first connecting surface 83 that is perpendicular to the first surface S1 and the second surface S2. The first sub-side surface 81 for connecting the first connecting surface 83 and the first surface S1, and the second sub-side surface 82 for connecting the first connecting surface 83 and the second surface S2 may be respectively disposed on two sides of the first connecting surface 83. The first sub-side surface 81 and the second sub-side surface 82 may be both inclined surfaces. The first sub-side surface 81 and the second sub-side surface 82 may be regarded as being obtained by chamfering the edges of the rectangular structure. When the first side surface CM1 is configured to the structure combining the vertical surface and the inclined surface and when the connecting wire L0 extends from the first surface S1 through the first side surface CM1 to the second surface S2, the connecting wire L0 may pass through the inclined first sub-side surface 81, the vertical first connecting surface 83, and the inclined second sub-side surface 82 in sequence. The first sub-side surface 81 may be configured as an inclined transition surface between the first surface S1 and the first connecting surface 83, and the second sub-side surface 82 may be configured as an inclined transition surface between the first surface S1 and the first connecting surface 83. The angle between the first sub-side surface 81 and the first surface S1 and the angle between the first sub-side surface 81 and the first connecting surface 83 may be both obtuse angles, and the angle between the second sub-side surface 82 and the first connecting surface 83 and the angle between the second sub-side surface 82 and the second surface S2 may be both obtuse angles. In such way, when routing the connecting wire L0, the connecting wire L0 may be avoided from passing through a relatively sharp right-angle region, and may be instead routed in an obtuse angle region or a plane region with a relatively gentle slope, which may be beneficial for improving the adhesion reliability of the connecting wire L0 on the first side surface CM1 and also beneficial for avoiding the problem of possible disconnection of the connecting wire L0 when passing through a sharp right-angle region. Furthermore, when the first side surface CM1 and the second side surface CM2 are both configured as a combination structure of the inclined surface and the vertical surface and when the first side surface CM1 and the second side surface CM2 form the encapsulation structure, it is beneficial for improving the adhesion reliability of the encapsulation structure on the first side surface CM1 and the second side surface CM2, thereby further being beneficial for improving encapsulation reliability of the encapsulation structure to the array substrate 10.

Referring to FIG. 4, in an optional embodiment of the present disclosure, the angle between the first sub-side surface 81 and the first surface S1 is α, and the angle between the second sub-side surface 82 and the second surface S2 is β, where α=β. In such way, the routing (wiring) arrangement at the obtuse angle region passed by the connecting wire L0 when extending from the first surface S1 to the first sub-side surface 81 may be same as the routing (wiring) arrangement at the obtuse angle region passed by the connecting wire L0 when extending from the second sub-side surface 82 to the second surface S2; and the force received of the connecting wire L0 may be same, which may be beneficial for improving overall force uniformity of the connecting wire L0 and the stability of the signal transmitted by the connecting wire L0.

Optionally, the angle between the first sub-side surface 81 and the first connecting surface 83, the angle between the second sub-side surface 82 and the first connecting surface 83, the angle between the first sub-side surface 81 and the first surface S1, and the angle between the second sub-side surface 82 and the second surface S2 may be all same. In such way, when the connecting wire L0 is routed on the first side surface CM1 and the second side surface CM2, the angle formed by the connecting wire L0 at the corner position may be consistent, which may be also beneficial for improving overall force uniformity of the connecting wire L0.

Referring to FIGS. 4-5, in an optional embodiment of the present disclosure, along the direction perpendicular to the first surface S1, the height of the first sub-side surface 81 is h1, and the height of the second sub-side surface 82 is h2, where h1=h2. When the angle α between the first sub-side surface 81 and the first surface S1 is equal to the angle β between the second sub-side surface 82 and the second surface S2, in embodiments of the present disclosure, it further configures the height h1 of the first sub-side surface 81 to be same as the height h2 of the second sub-side surface 82. According to the Pythagorean theorem, the length of the first sub-side surface 81 may be same as the length of the second sub-side surface 82. The first sub-side surface 81 and the second sub-side surface 82 may be equivalent to being symmetrically distributed on two sides of the first connecting surface 83. The symmetrical configuration manner may be also beneficial for improving the force uniformity of the connecting wire L0 when the connecting wire L0 is routed on the first side surface CM1 and the second side surface CM2. Meanwhile, the first sub-side surface 81 and the second sub-side surface 82 may also be formed by a cutting process, which may be beneficial for simplifying cutting process and improving fabrication efficiency.

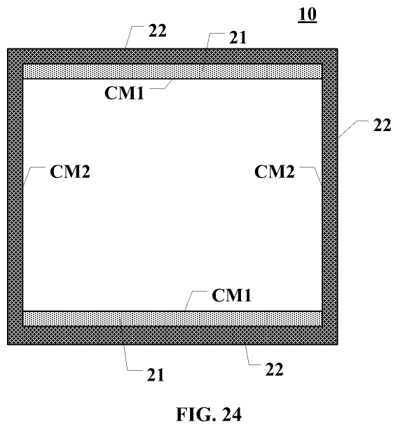

Optionally, referring to FIGS. 6 and 13, above-mentioned embodiments describe the solution that the display panel includes one first side surface CM1 and three second side surfaces CM2, and the first side surface CM1 is adjacent to the second side surface CM2. At this point, the connecting wire L0 may be disposed on the back of the display panel from the first side surface CM1; and the encapsulation structure corresponding to single first side surface CM1 may refer to above-mentioned embodiments, and the encapsulation structure corresponding to each second side surface CM2 may also refer to above-mentioned embodiments. In addition, in some other embodiments of the present disclosure, referring to FIGS. 23-24, the display panel may include two first side surfaces CM1 and two second side surfaces CM2; two first side surfaces CM1 may be arranged opposite to each other; and the first side surface CM1 may be adjacent to the second side surface CM2. FIG. 23 illustrates another planar schematic of the display panel according to various embodiments of the present disclosure; and FIG. 24 illustrates another top view of the array substrate 10 and the encapsulation structure on the side of the array substrate 10 according to various embodiments of the present disclosure. When two first side surfaces CM1 are configured at the display panel, two first side surfaces CM1 may be configured to be opposite to each other in one embodiment. The connecting wire L0 may be routed from two first side surfaces CM1 configured to be opposite to each other. Two first side surfaces CM1 configured to be opposite to each other may use same first encapsulation structure 91, and two second side surfaces CM2 configured to be opposite to each other may use same second encapsulation structure 92. In such way, it may be beneficial for achieving the symmetry of the encapsulation structures in the display panel and improving overall visual effect of the display panel.

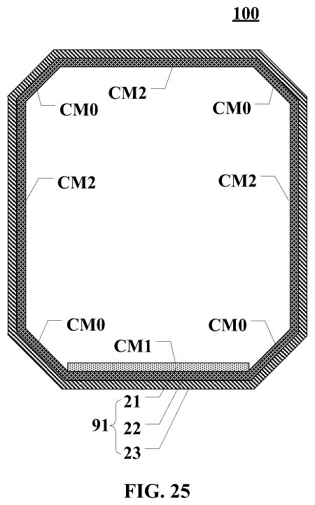

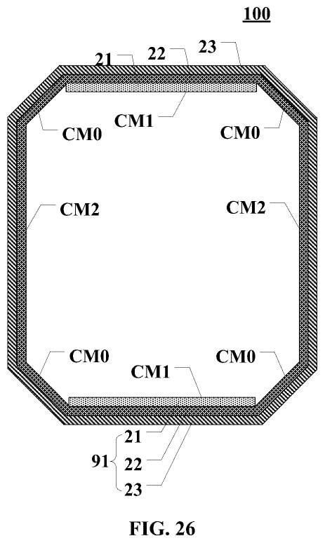

FIGS. 25-26 respectively show another planar schematic of the display panel provided by embodiments of the present disclosure. Referring to FIGS. 1-3, in an optional embodiment of the present disclosure, the side of the array substrate 10 may further include a transition surface CM0; the transition surface CM0 may be configured to connect the first side surface CM1 and the second side surface CM2 which are adjacent to each other, and/or, the transition surface CM0 may be configured to connect adjacent second side surfaces CM2; and along the direction perpendicular to the first surface S1, the angle between the orthographic projection of the transition surface CM0 and the orthographic projection of the side surface connected thereto may be an obtuse angle.

In one embodiment of FIG. 25, the array substrate 10 may include one first side surface CM1 and three second side surfaces CM2; the first side surface CM1 may be adjacent to two second side surfaces CM2 respectively; the second side surface CM2 arranged opposite to the first side surface CM1 may be also adjacent to other two second side surfaces CM2 respectively; the transition surface CM0 may be configured between the first side surfaces CM1 and the second side surfaces CM2 which are adjacent to each other; and the transition surface CM0 may be also configured between adjacent two second side surfaces CM2. In one embodiment of FIG. 26, the array substrate 10 may include two first side surfaces CM1 and two second side surfaces CM2; two first side surfaces CM1 may be arranged opposite to each other; two second side surfaces CM2 may be arranged opposite to each other; the first side surface CM1 may be adjacent to two second side surfaces CM2; the second side surface CM2 may be adjacent to two first side surfaces CM1; and the transition surface CM0 may be configured between the first side surfaces CM1 and the second side surfaces CM2 which are adjacent to each other. Above-mentioned transition surface CM0 may be regarded as obtained by cutting the four corners of the display panel with rectangular structure.

In the existing technology, the display panel may be embodied as a rectangular structure; and corresponding four corners may be right angles. For the display panel without a frame or an extremely narrow frame, the edge of the panel may need to be processed by cutting and fine edge grinding processes during the fabrication process. Since above right-angle region corresponds to two side surfaces, the right-angle region may be an overlapping region that needs to be fabricated by two edge grindings. Due to the limitation of the processing technology, it may easily cause four corner regions of the display panel to collapse and then cause problems such as cracks in the substrate, which may affect the reliability of the panel. Furthermore, the existence of the right-angle corner portion may easily cause corner chipping caused by bumps during the splicing process of the display panel.

To solve above-mentioned problems, in embodiments of the present disclosure, corner cutting design may be performed on the four corner regions of the array substrate 10. In such way, the side of the array substrate 10 may include the transition surface CM0 connecting the first side CM1 and the second side CM2 which are adjacent to each other, or connecting adjacent second sides CM2; and the angle between the orthographic projection of the transition surface CM0 and the orthographic projection of the side connected thereto may be an obtuse angle, which may avoid the existence of sharp right-angle regions, thereby being beneficial for avoiding chipping in the four right-angle regions and further avoiding the problem of cracks caused by chipping. After the transition surface CM0 is formed, only obtuse angles may exist in the edge regions of the display panel, and no sharp right angles may exist, thereby avoiding the problem of chipping caused by bumps during the splicing process of the display panel.

It should be noted that when the first side surface CM1 and the second side surface CM2 are embodied as the structure combining the inclined surface and the vertical surface as shown in FIGS. 4-5, the transition surface CM0 may also be embodied as same structure as the first side surface CM1 and the second side surface CM2.

Referring to FIGS. 25-26, in an optional embodiment of the present disclosure, along the direction perpendicular to the first surface S1, the angle between the transition surface CM0 and the orthographic projections of one side surface connected to the transition surface CM0 may be same as the angle between the transition surface CM0 and the orthographic projections of another side surface connected to the transition surface CM0. That is, when the angle is cut, the cut portion may be an isosceles right triangle. Optionally, the sizes of the four isosceles right triangles being cut may be equal to each other, which may be beneficial for improving the visual consistency of the region where the transition surface CM0 of the display panel is located.

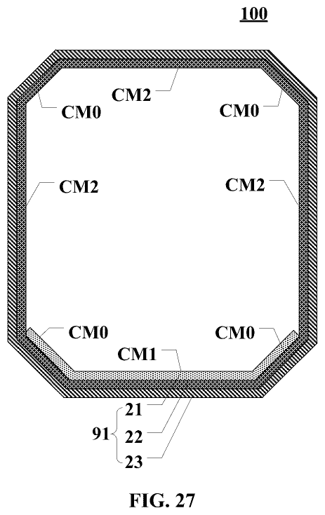

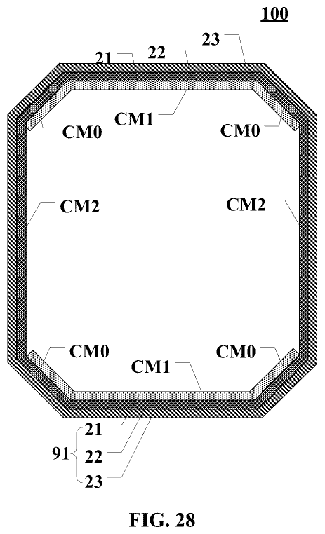

FIGS. 27-28 respectively illustrate another planar schematic of the display panel provided by embodiments of the present disclosure. Referring to FIGS. 25-28, in an optional embodiment of the present disclosure, the encapsulation structure may include the first encapsulation structure 91 on the first side CM1, the first encapsulation structure 91 may include the wire encapsulation layer 21, and the wire encapsulation layer 21 may be in direct contact with the connecting wire L0 and the first side CM1. Referring to FIGS. 25-26, along the circumferential direction of the projection of the side surface on the first surface S1, the wire encapsulation layer 21 may be only on the first side CM1; or referring to FIGS. 27-28, the wire encapsulation layer 21 may be on the first side CM1 and the transition surface CM0 connected to the first side CM1.

The first side surface CM1 may be disposed with the connecting wire L0, such that the wire encapsulation layer 21 may be configured to be in direct contact with the connecting wire L0 to encapsulate the connecting wire L0. The filling encapsulation layer 22 may be disposed on entire side surface of the array substrate 10. The difference between one embodiment shown in FIGS. 25-26 and one embodiment shown in FIGS. 27-28 is that the coverage of the wire encapsulation layer 21 may be different. In one embodiment shown in FIGS. 25-26, the wire encapsulation layer 21 may be only on the first side surface CM1 where the connecting wire L0 is disposed. Such manner may encapsulate the connecting wire L0 specifically, and the transition surface CM0 connected to the first side surface CM1 may also be configured as a reference for the cutoff position of the wire encapsulation layer 21, which may simplify the fabrication process of the wire encapsulation layer 21. In one embodiment shown in FIGS. 27-28, the wire encapsulation layer 21 may extend from the first side surface CM1 to at least a part of the transition surface CM0 adjacent to the first side surface CM1. Such configuration may be equivalent to increasing the coverage region of the wire encapsulation layer 21, and while achieving full coverage of the connecting wire L0 of the first side surface CM1, certain extension of the wire encapsulation layer 21 may be performed, which may be beneficial for further improving encapsulation reliability of the wire encapsulation layer 21 for the connecting wire L0.

Referring to FIGS. 25-28, in an optional embodiment of the present disclosure, the encapsulation structure may further include the filling encapsulation layer 22 and the light-blocking encapsulation layer 23 arranged corresponding to the transition surface CM0. On the transition surface CM0, the filling encapsulation layer 22 may be between the transition surface CM0 and the light-blocking encapsulation layer 23.

When the transition surface CM0 is disposed between the first side surface CM1 and the second side surface CM2 which are adjacent to each other, and between adjacent second side surfaces CM2, in embodiments of the present disclosure, the filling encapsulation layer 22 and the light-blocking encapsulation layer 23 may be also disposed on one side of the transition surface CM0, which may be beneficial for preventing external moisture and oxygen from penetrating into the display panel from the position of the transition surface CM0, thereby being beneficial for improving overall encapsulation reliability of the display panel.

Referring to FIGS. 25-28, in an optional embodiment of the present disclosure, the encapsulation structure may include the filling encapsulation layer 22 and the light-blocking encapsulation layer 23 corresponding to the first side CM1 and the second side CM2. The filling encapsulation layer 22 on the first side CM1, the second side CM2 and the transition surface CM0 may be made of a same material using a same process; and the light-blocking encapsulation layer 23 on the first side CM1, the second side CM2 and the transition surface CM0 may be made of a same material using a same process.

In actual fabrication, the wire encapsulation layer 21 may be first formed at the position corresponding to the first side surface CM1, such that the wire encapsulation layer 21 may be at least on the first side surface CM1, at least a part of the first surface S1 and at least a part of the second surface S2, and may cover all the connecting wires L0 on the first side surface CM1 and cover at least a part of the connecting wires L0 on the first surface S1 and the second surface S2. After the wire encapsulation layer 21 is completed, the filling encapsulation layer 22 may be formed on the first side surface CM1, the second side surface CM2 and the transition surface CM0 using a same process, and there is no need to introduce different fabrication processes for different side surfaces and the transition surface CM0, which may be beneficial for simplifying the fabrication process. Furthermore, when the filling encapsulation layer 22 is formed on different side surfaces and the transition surface CM0 using a same process, the filling encapsulation layer 22 in the encapsulation structure may form an integral closed structure, which may avoid the problem that the encapsulation effect may be affected due to gaps existing between the filling encapsulation layers 22 in different regions when different processes are used, thereby also being beneficial for improving encapsulation reliability of the filling encapsulation layer 22. After the filling encapsulation layer 22 is fabricated, the light-blocking encapsulation layer 23 on different side surfaces and the transition surface CM0 may be formed using a same process, such that the light-blocking encapsulation layer 23 may form an integral closed structure, which may also avoid the problem that the encapsulation effect and the light-blocking effect may be affected due to gaps existing between the filling light-blocking encapsulation layers 23 in different regions when different processes are used. Therefore, the light-blocking encapsulation layers 23 in different regions may be formed using a same process, which may be also beneficial for improving overall light-blocking effect and the encapsulation effect of the light-blocking encapsulation layer 23.

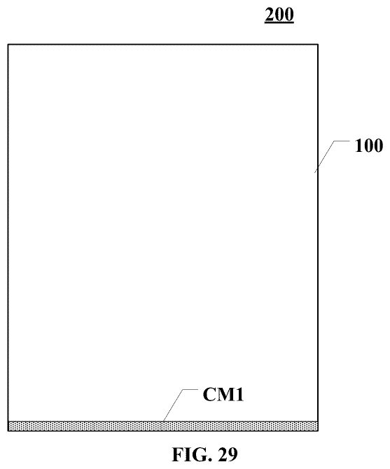

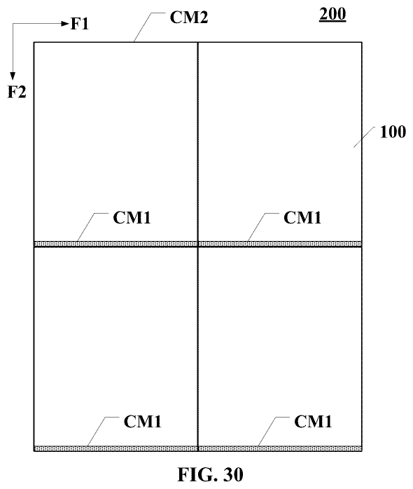

Based on same inventive concept, the present disclosure further provides a display apparatus. FIG. 29 illustrates a structural schematic of a display apparatus according to various embodiments of the present disclosure. Referring to FIG. 29, a display apparatus 200 may include the display panel 100 in any of above-mentioned embodiments. The display apparatus 200 provided in embodiments of the present disclosure may be any electronic device with display function, such as a tablet computer with touch and display functions, a display product, a television, a car display apparatus or the like, and may be particularly suitable for the display apparatus with an extremely narrow frame or no frame. The display apparatus 200 provided in embodiments of the present disclosure may have the beneficial effect of the display panel 100 provided in embodiments of the present disclosure, which may refer to description of the display panel 100 in above-mentioned embodiments and may not be described in detail herein.

It can be understood that FIG. 29 may only illustrate the display apparatus in a rectangular structure. In some other embodiments of the present disclosure, the display apparatus 200 may also be embodied as a circle, an ellipse or any other feasible shape, which may be not limited in the present disclosure.

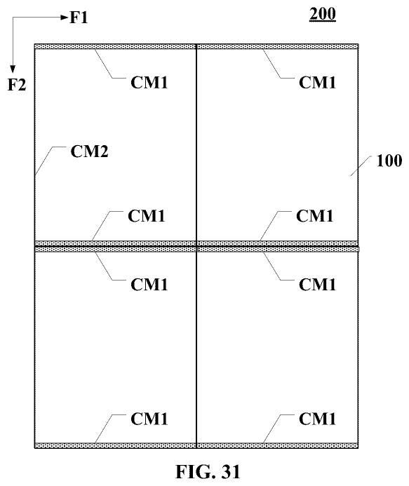

FIGS. 30-31 respectively illustrate another structural schematic of the display apparatus provided by embodiments of the present disclosure. Referring to FIGS. 30-31, in an optional embodiment of the present disclosure, the display apparatus may include at least two display panels spliced along the first direction F1; the first side surface CM1 may be on at least one side of the display panel along the second direction F2, and the first direction F1 may intersect the second direction F2; and/or, the first side surface CM1 may be on at least one side of the display panel along the first direction F1.

It should be noted that embodiments shown in FIGS. 30-31 may be only described by taking the display apparatus formed by splicing four display panels as an example, which may not limit the quantity of display panels (actually) included in the display apparatus. The spliced display apparatus may include at least two display panels. In one embodiment shown in FIG. 30, it illustrates the scenario that the display panel may include only one first side surface CM1. It is assumed that the display apparatus includes the upper edge and the lower edge extending along the first direction F1 and arranged oppositely along the second direction F2. At this point, the first side surface CM1 of each display panel may be on the side of the second side surface CM2 opposite to the first side surface CM1 and facing toward the lower edge of the display panel; or the first side surface CM1 of each display panel may be on the side of the second side surface CM2 opposite to the first side surface CM1 and facing toward the upper edge of the display panel. In one embodiment shown in FIG. 31, it illustrates the scenario that the display panel may include two first side surfaces CM1 arranged oppositely. It is assumed that the display apparatus includes the upper edge and the lower edge extending along the first direction F1 and arranged oppositely along the second direction F2. At this point, two first side surfaces CM1 of each display panel in the display apparatus may be arranged oppositely along the second direction F2. During actual splicing, the arrangement directions of the first side surfaces CM1 in different display panels may be flexibly set according to actual conditions, which may be not limited in the present disclosure.

It may be seen from above-mentioned embodiments that the present disclosure may at least achieve following beneficial effects.

In the display panel and the display apparatus provided by the present disclosure, the connecting wire may be disposed on the first side, while the connecting wire may be not disposed on the second side. For whether the connecting wire is disposed, the encapsulation structure at the first side and the encapsulation structure at the second side may be differentially designed in the present disclosure, such that the encapsulation structure at the first side may be different from the encapsulation structure at the second side. For example, for the first side disposed with the connecting wire, if the connecting wire is affected by external moisture, oxygen and the like, corrosion and other problems may occur to affect the reliability of signal transmission on the connecting wire. Therefore, the first side may have higher requirement for encapsulation, and the encapsulation structure with higher encapsulation reliability may be disposed at the position of the first side. For the second side where the connecting wire is not disposed, the encapsulation requirement may be lower than the encapsulation requirement of the first side, so that there is no need to overprotect the second side. While ensuring effective encapsulation of the second side, unnecessary encapsulation film layers may be avoided to be disposed to simplify the encapsulation process of the second side and reduce the fabrication cost.

It should be noted that in the present disclosure, relational terms such as “first” and “second” may be only configured to distinguish one entity or operation from another entity or operation and may not necessarily require or imply that such actual relationship or order is between these entities or operations. Furthermore, the terms “comprise”, “include” or any other variation thereof may be intended to cover a non-exclusive inclusion. Therefore, a process, a method, an article or apparatus including a set of elements may include not only those elements, but also other elements not expressly listed, or also include elements inherent in the process, the method, the article or apparatus. Without further limitations, an element defined by the statement “include . . . ” may not exclude the presence of additional identical elements in the process, the method, the article, or apparatus including such element.

The above may be merely embodiments of the present disclosure, which may make those skilled in the art to understand or implement the present disclosure. Various modifications to embodiments of the present disclosure may be apparent to those skilled in the art. General principles defined in the present disclosure may be implemented in other embodiments without departing from the spirit or scope of the present disclosure. Therefore, the present disclosure may not be limited to embodiments described in the present disclosure but may be accorded the widest scope consistent with the principles and novel features of the present disclosure.

What is claimed is

1. A display panel, comprising:
an array substrate, including a first surface and a second surface arranged opposite to each other along a direction perpendicular to a light-exiting surface of the display panel, and a plurality of side surfaces connecting the first surface and the second surface, wherein the plurality of side surfaces includes a first side surface and a second side surface;
a plurality of first soldering pads and a plurality of second soldering pads, wherein the plurality of first soldering pads is at the first side, and the plurality of second soldering pads is at the second side;
a plurality of connecting wires at least at the first side, wherein the plurality of connecting wires is configured to connect the plurality of first soldering pads and the plurality of second soldering pads; and no connecting wire is disposed on the second side; and
a plurality of encapsulation structures, at least covering the plurality of side surfaces of the array substrate, wherein an encapsulation structure at the first side is different from an encapsulation structure at the second side.

2. The display panel according to claim 1, wherein:
the plurality of encapsulation structures includes a first encapsulation structure at the first side and a second encapsulation structure at the second side; and a quantity of encapsulation layers included in the first encapsulation structure is greater than a quantity of encapsulation layers included in the second encapsulation structure.

3. The display panel according to claim 2, wherein:
the first encapsulation structure includes a quantity M of encapsulation layers stacked with each other, and the second encapsulation structure includes a quantity N of encapsulation layers stacked with each other, wherein M−N≥1, M≥2, and N≥1.

4. The display panel according to claim 2, wherein:
the first encapsulation structure includes a wire encapsulation layer and a filling encapsulation layer; on a side of the first side away from the array substrate, the wire encapsulation layer is in a direct contact with a connecting wire and the filling encapsulation layer; and at least a part of the wire encapsulation layer is between the connecting wire and the filling encapsulation layer.

5. The display panel according to claim 2, wherein:
the second encapsulation structure includes a filling encapsulation layer; and on a side of the second side surface away from the array substrate, the filling encapsulation layer is in a direct contact with the second side surface.

6. The display panel according to claim 4, further including:
light-emitting elements electrically connected to the array substrate and on the first surface, wherein at least a part of the filling encapsulation layer is on a side of the first surface away from the second surface; and a distance between the second surface and a surface of a light-emitting element away from the first surface is H0, and a distance between the second surface and a surface of the filling encapsulation layer away from the first surface is H1, wherein H1>H0.

7. The display panel according to claim 6, further including:
a first light-blocking layer and a light-transmitting layer on the first surface, wherein:
the first light-blocking layer is at least partially between adjacent light-emitting elements; and the light-transmitting layer is on a side of the first light-blocking layer away from the first surface and covers the light-emitting element and at least a part of the first light-blocking layer; and
the filling encapsulation layer is in a contact with side surfaces of the first light-blocking layer and the light-transmitting layer.

8. The display panel according to claim 4, further including:
a first light-blocking layer and light-emitting elements electrically connected to the array substrate and on the first surface, wherein:
the first light-blocking layer is at least partially between adjacent light-emitting elements; and
a distance between the second surface and a surface of a light-emitting element away from the first surface is H0, a distance between the second surface and a surface of the first light-blocking layer away from the first surface is H2, and a distance between the second surface and a surface of the filling encapsulation layer away from the first surface is H1, wherein H0≥H2≥H1.

9. The display panel according to claim 8, further including:
a light-transmitting layer, which is on a side of the first light-blocking layer away from the first surface and covers the light-emitting element and at least a part of the first light-blocking layer, wherein the filling encapsulation layer is in a contact with a side surface of the first light-blocking layer.

10. The display panel according to claim 4, wherein:
the first encapsulation structure and the second encapsulation structure include a light-blocking encapsulation layer; and the light-blocking encapsulation layer is at least partially on a side of the filling encapsulation layer away from the first side surface.

11. The display panel according to claim 10, further including:
a first light-blocking layer and light-emitting elements electrically connected to the array substrate and on the first surface, wherein:
the first light-blocking layer is at least partially between adjacent light-emitting elements; and
the light-blocking encapsulation layer includes a main body portion and a first extension portion connected to the main body portion; the main body portion is on a side of the filling encapsulation layer away from the first side surface; the first extension portion is at a light-exiting side of a light-emitting element; and the first extension portion is not overlapped with the light-emitting element along a direction perpendicular to a plane of the array substrate.

12. The display panel according to claim 11, wherein:
along the direction perpendicular to the plane of the array substrate, a distance between the first extension portion and a surface of the light-emitting element away from the array substrate is greater than 0; or
along the direction perpendicular to the plane of the array substrate, the first extension portion is overlapped with a first soldering pad; or
along the direction perpendicular to the plane of the array substrate, the first extension portion is overlapped with the first light-blocking layer.

13. The display panel according to claim 11, wherein:
along a direction of the first surface pointing to the first side surface, a width of the first extension portion is D01, and a width of the filling encapsulation layer is D02, wherein D01≥D02.

14. The display panel according to claim 11, wherein:
the first extension portion includes a first sub-extension portion corresponding to the first encapsulation structure and a second sub-extension portion corresponding to the second encapsulation structure; and along a direction of the first surface pointing to the first side surface, a width of the first sub-extension portion is D011, and along a direction of the first surface pointing to the second side surface, and a width of the second sub-extension portion is D012, wherein D011>D012.

15. The display panel according to claim 11, wherein:
along a direction of the first surface pointing to the first side surface, a width of the first extension portion is D01, wherein 0<D01≤100 μm.

16. The display panel according to claim 11, wherein:
the first extension portion and the main body portion are formed into a single piece; or
along the direction perpendicular to the plane of the array substrate, a distance between the first extension portion and the filling encapsulation layer is greater than 0.

17. The display panel according to claim 16, further including:
a light-transmitting layer and a first protection layer, wherein:
the light-transmitting layer is on a side of the first light-blocking layer and the light-emitting element away from the first surface; and the first protection layer is on a side of the light-transmitting layer away from the first surface; and
the first extension portion is on a surface of the first protection layer away from the light-transmitting layer, and the filling encapsulation layer is on a side of the first protection layer facing toward the array substrate.

18. The display panel according to claim 17, further including:
an encapsulation protection layer, wherein on a side of the first surface away from the second surface, the encapsulation protection layer is on a side of the first extension portion and the first protection layer away from the first surface; and along the direction perpendicular to the plane of the array substrate, the encapsulation protection layer is at least overlapped with an edge of the first extension portion.

19. The display panel according to claim 18, wherein:
the encapsulation protection layer includes a plurality of microstructures arranged along the edge of the first extension portion; and a projection of a microstructure on the first surface includes an arc-shaped edge; and
along the direction perpendicular to the plane of the array substrate, the projection of the microstructure on the first surface covers at least a part of a side surface of the first extension portion.

20. A display apparatus, comprising:
a display panel, comprising:
an array substrate, including a first surface and a second surface arranged opposite to each other along a direction perpendicular to a light-exiting surface of the display panel, and a plurality of side surfaces connecting the first surface and the second surface, wherein the plurality of side surfaces includes a first side surface and a second side surface;
a plurality of first soldering pads and a plurality of second soldering pads, wherein the plurality of first soldering pads is at the first side, and the plurality of second soldering pads is at the second side;
a plurality of connecting wires at least at the first side, wherein the plurality of connecting wires is configured to connect the plurality of first soldering pads and the plurality of second soldering pads; and no connecting wire is disposed on the second side; and
a plurality of encapsulation structures, at least covering the plurality of side surfaces of the array substrate, wherein an encapsulation structure at the first side is different from an encapsulation structure at the second side.
